(19) United States
(12) Patent Application Publication
(10) Pub. No.: US 2014/0042518 A1
(43) Pub. Date: Feb. 13, 2014

(54) SEMICONDUCTOR DEVICE AND METHOD OF MANUFACTURING THE SAME

(71) Applicant: SK HYNIX INC., Gyeonggi-do (KR)

(72) Inventor: Jung Myoung SHIM, Gyeonggi-do (KR)

(73) Assignee: SK HYNIX INC., Gyeonggi-do (KR)

(21) Appl. No.: 13/716,035

(22) Filed: Dec. 14, 2012

(30) Foreign Application Priority Data
Aug. 10, 2012 (KR) 10-2012-0087749

(51) Int. Cl. H01L 29/423; H01L 29/40

(52) U.S. Cl. CPC H01L 29/42328; H01L 29/401
USPC 257/321; 438/422

(57) ABSTRACT

A semiconductor device includes isolation layers formed in isolation regions defined between active regions of a semiconductor substrate, wherein each of the isolation layers includes a first air gap, word lines formed over the semiconductor substrate in a direction crossing the isolation layers, wherein each of the word lines includes a stacked structure of a tunnel insulating layer, a floating gate, a dielectric layer and a control gate, and including insulating layers between the word lines, wherein a width of the floating gate is greater than a width of each active region.

### CROSS-REFERENCE TO RELATED APPLICATION

Priority is claimed to Korean patent application number 10-2012-0087749, filed on Aug. 10, 2012, the entire disclosure of which is incorporated herein by reference in its entirety.

### BACKGROUND

1. Field of Invention

Embodiments of the present invention relate to a semiconductor device and a method of manufacturing the same and, more particularly, to a semiconductor device including an isolation region and a method of manufacturing the same.

2. Description of Related Art

When semiconductor devices are manufactured, isolation layers are formed in isolation regions so as to isolate each semiconductor devices formed on a semiconductor substrate from one another. As for semiconductor devices including memory cells, narrow isolation layers in a memory array are arranged at regular intervals between active regions.

As widths of isolation regions are reduced to increase a degree of integration of a semiconductor device, widths of isolation layers are accordingly reduced. A parasitic capacitor is formed by adjacent active regions and isolation layers interposed therebetween. As the widths of the isolation layers are reduced, parasitic capacitance may increase. An increase in parasitic capacitance may result in significant interference between the active regions (i.e., channel regions of memory cells). As a result, electrical characteristics of the semiconductor device may be deteriorated.

### BRIEF SUMMARY

An embodiment of the present invention relates to a semiconductor device suppressing interference and a method of manufacturing the same.

In accordance with an exemplary embodiment of the present invention, a semiconductor device according to an embodiment of the present invention includes isolation layers formed in isolation regions defined between active regions of a semiconductor substrate, wherein each of the isolation layers includes a first air gap, word lines formed over the semiconductor substrate in a direction crossing the isolation layers, wherein each of the word lines includes a stacked structure of a tunnel insulating layer, a floating gate, a dielectric layer and a control gate, and including insulating layers between the word lines, wherein a width of the floating gate is greater than a width of each active region.

In accordance with an exemplary embodiment of the present invention, a method of manufacturing a semiconductor device according to an embodiment of the present invention includes stacking tunnel insulating layers and silicon layers in active regions of the semiconductor substrate and forming trenches in isolation regions between the active regions, forming grown layers on sidewalls of the silicon layers, forming isolation layers for filling the trenches and spaces between the silicon layers and forming first air gaps therein, forming a dielectric layer and a conductive layer over the semiconductor substrate including the isolation layers, and forming word lines by patterning the conductive layer, the dielectric layer, the silicon layers and the grown layers.

In accordance with an exemplary embodiment of the present invention, a semiconductor device includes isolation layers formed in isolation regions defined between active regions of a semiconductor substrate, wherein each of the isolation layers includes an air gap and floating gates each of which is formed over the semiconductor substrate in a direction crossing the isolation layers, wherein a top portion of the air gap is disposed within a height range of said each floating gate and between the floating gates.

### BRIEF DESCRIPTION OF THE DRAWINGS

FIGS. 1 to 10 are cross-sectional views illustrating a process flow for manufacturing a semiconductor device according to an embodiment of the present invention.

### DESCRIPTION OF EMBODIMENTS

Hereinafter, various embodiments of the present disclosure will be described in detail with reference to the accompanying drawings. In the drawings, thickness and distance of components are exaggerated compared to the actual physical thickness and distance of intervals for the convenience of illustration. In the following description, detailed explanation of known-related functions and constitutions may be omitted to avoid unnecessarily obscuring the subject manner of the present invention.

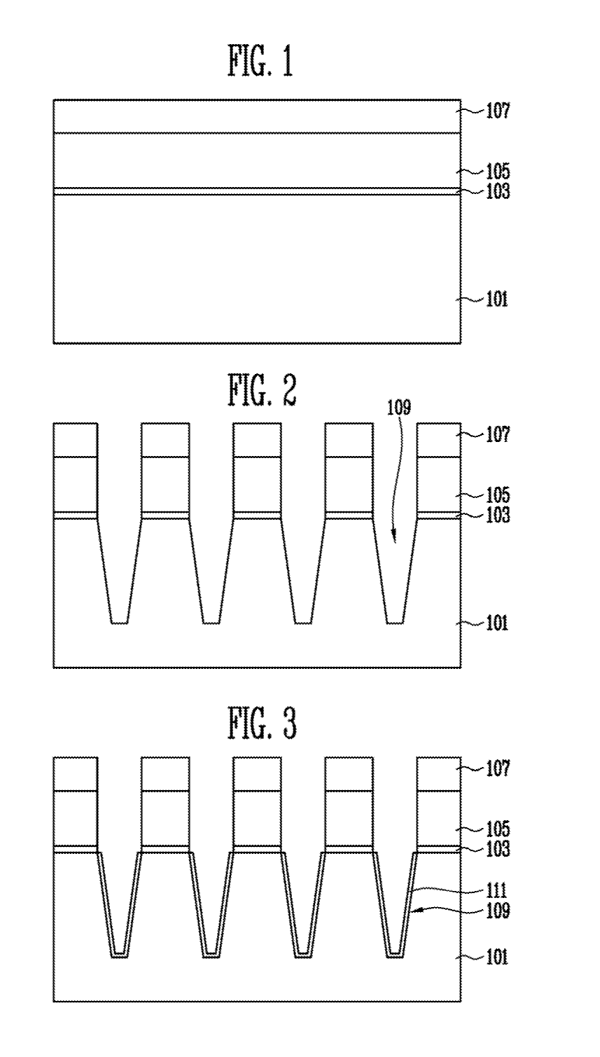

FIGS. 1 to 10 are cross-sectional views illustrating a process flow for manufacturing a semiconductor device according to an embodiment of the present invention. FIGS. 1 to 7 are cross-sectional views taken in a word line direction. FIGS. 8 to 10 are cross-sectional views taken in a direction (e.g., a bit direction) crossing the word line direction.

Referring to FIG. 1, a well (not illustrated) may be formed in a semiconductor substrate 101. A P type substrate may be used as the semiconductor substrate 101. A N well and a P well may be formed in the semiconductor substrate 101 by implanting impurities into the semiconductor substrate 101. In addition, the P well may be formed in the N well after the N well is formed in the semiconductor substrate 101. Processes described below may be performed on the semiconductor substrate 101 in which the P well is formed.

A tunnel insulating layer 103 may be formed on the semiconductor substrate 101. The tunnel insulating layer 103 may be formed in a cell region, and gate insulating layers of transistors including a low-voltage transistor and a high-voltage transistor may be formed in a peripheral region (not illustrated). Hereinafter, the cell region is mainly described.

A silicon layer 105 may be formed on the tunnel insulating layer 103. The silicon layer 105 may include a doped polysilicon layer with 3-valence impurities or 5-valence impurities and may be used as a floating gate. The silicon layer 105 may have a stacked structure including an undoped silicon layer and a doped polysilicon layer.

A hard mask layer 107 may be formed on the silicon layer 105. The hard mask layer 107 may include an oxide layer or a nitride layer, or a stacked structure including an oxide layer and a nitride layer.

Referring to FIG. 2, the hard mask layer 107, the silicon layer 105 and the tunnel insulating layer 103 may be etched from isolation regions. As a result, the hard mask layer 107, the silicon layer 105 and the tunnel insulating layer 103 may remain on the semiconductor substrate 101 in active regions defined between the isolation regions. A width of the remaining silicon layer 105 may correspond to a width of the active region.

When the hard mask layer 107, the silicon layer 105 and the tunnel insulating layer 103 are etched, the semiconductor substrate 101 formed in the isolation regions may be exposed. Subsequently, exposed portions of the semiconductor substrate 101 may be etched to form trenches 109. The trenches 109 in the cell region may have parallel linear shapes.

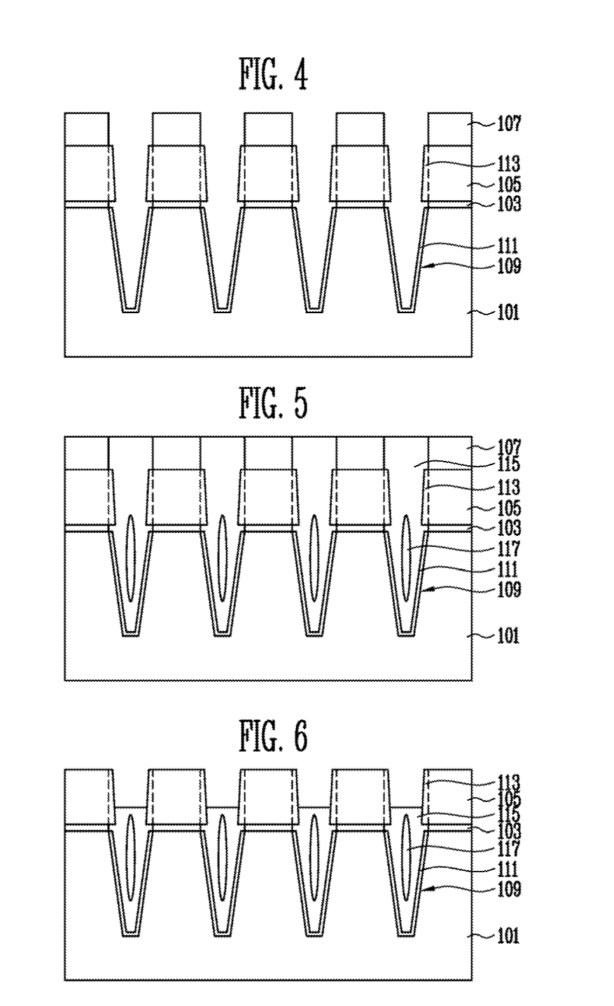

Referring to FIG. 3, growth inhibiting layers 111 may be formed along the sidewalk and bottom of the trenches 109. Each of the growth inhibiting layers 111 may include an insulating layer through oxidation or deposition. For example, the growth inhibiting layer 111 may include an oxide layer or a nitride layer.

More specifically, an insulating layer may be farmed over the entire surface of the semiconductor substrate 101 including the trenches 109. Subsequently, an etch process may be performed so that the insulating layer may remain along the sidewalls and bottom of the trenches 109. The etch process may be performed to remove the insulating layer formed on surfaces of the silicon layers 105. In order to remove the insulating layer formed along sidewalk of the silicon layers 105, the etch process may be performed by using dry etching.

In addition, in order to remove the insulating layer formed along the sidewalls of the silicon layers 105 while leaving the insulating layer formed along the sidewalk and bottom of the trenches 109, an etched angle of inclination of the semiconductor substrate 101 may be appropriately controlled during the etch process by using dry etching. Meanwhile, edges of the tunnel insulating layer 103 may also be etched when the insulating layer is removed. Therefore, the insulating layer may remain on the sidewalls of the silicon layers 105. As a result, the growth inhibiting layers 111 may include the insulating layer formed along the exposed sidewalls and bottom of the trenches 109.

Referring to FIG. 4, grown layers 113 may be formed on the sidewalls of the silicon layers 105. The grown layers 113 may be formed using Selective Epitaxial Growth (SEG). The grown layers 113 may be formed on the sidewalk of the silicon layers 105 and located above the isolation regions. The grown layers 113 may protrude from the silicon layers 105. The silicon layers 105 may provide narrow entrances for the trenches 109. In addition, since the grown layers 113 are formed along the sidewalk of the silicon layers 105, a width of a floating gates comprised of the same may be greater than that of the active region.

The above-described SEG may be performed after the hard mask layer 107 is removed. In this case, the grown layers 113 may be formed over a top surface of the silicon layer 105 and on the sidewalls of the silicon layer 105.

With reference to FIG. 5, isolation layers 115 may be formed at the isolation regions of the semiconductor substrate 101 so as to fill the trenches 109 and spaces between the silicon layers 105. Since the entrances of the trenches 109 are narrow due to the grown layers 113 formed along the sidewalls of the silicon layers 105, the trenches 109 may not be completely filled with the isolation layers 115, consequently forming air gaps 117 in the isolation layers 115.

The air gaps 117 formed in the isolation layers 115 may extend in parallel with the isolation regions. In addition, a top portion of each air gap 117 may be located within the height range of the silicon layer 105 and between the silicon layers 105.

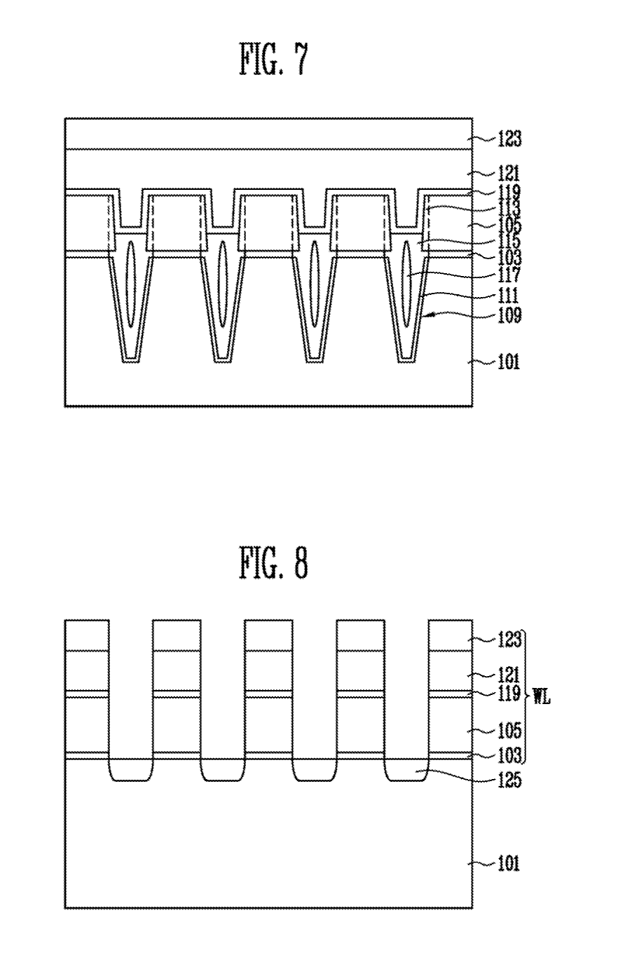

Referring to FIG. 6, top portions of the isolation layers 115 may be etched, so that the isolation layers 115 may have heights defined from the trenches 109 to the silicon layers 105. When the top portion of the isolation layer 115 is etched, an etched thickness of the isolation layer 115 may be controlled so as not to expose the air gap 117 formed in the isolation layer 115.

As the top portions of the isolation layers 115 are etched, upper sidewalls of the grown layers 113 may be exposed. As a result, a coupling ratio between the grown layers 113 and a conductive layer configured as a control gate to be formed through subsequent processes may increase.

Referring to FIG. 7, a dielectric layer 119, a conductive layer 121 and a hard mask layer 123 may be sequentially formed over the entire structure of the semiconductor substrate 101 including the isolation layers 115. The dielectric layer 119 may have a stacked structure including an oxide layer, a nitride layer and an oxide layer. Here, the oxide layer or the nitride layer may be replaced by a high dielectric insulating layer. The conductive layer 121 may have a stacked structure of a doped polysilicon layer and a metal layer. Here, a metal silicide layer (e.g., tungsten silicide layer, titanium silicide layer or cobalt silicide layer) may replace the metal layer.

Referring to FIG. 8, the hard mask layer 123, the conductive layer 121, the dielectric layer 119, the grown layers 113 and the silicon layers 105 may be patterned to form word lines WL extending in a direction crossing the isolation layers 115. Subsequently, junctions (or impurity regions) 125 that function as source/drain may be formed by implanting impurities into the active regions of the semiconductor substrate 101 exposed between the word lines WL. The impurity regions 125 may be formed by implanting 5-valence impurities, such as phosphorus or arsenic, into the semiconductor substrate 101.

Subsequently, insulating layers may be formed between the word lines WL. This will be described below in detail.

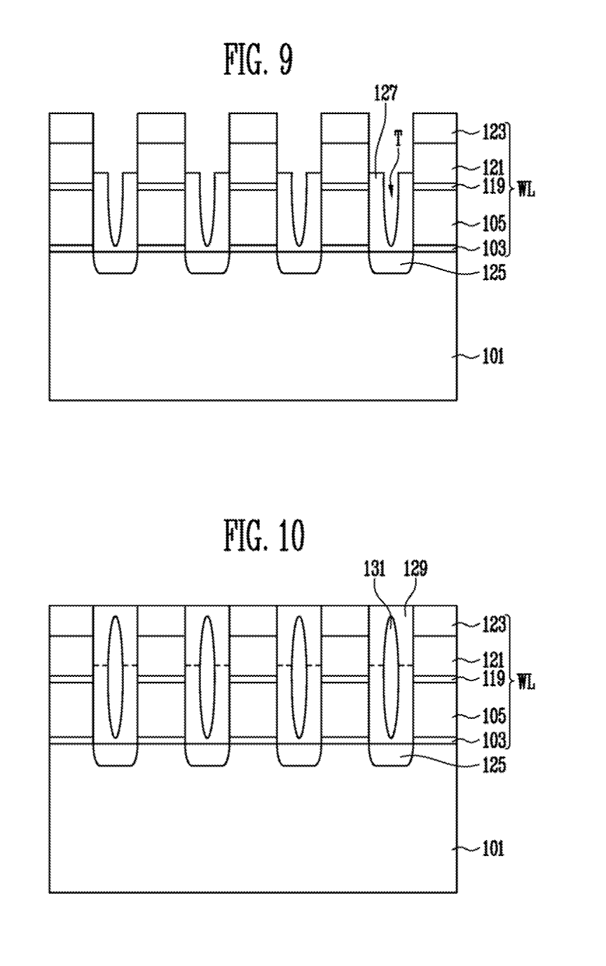

Referring to FIG. 9, first insulating layers 127 may be formed between the word lines WL by using materials having poor step coverage (e.g., USG). Subsequently, top portions of the first insulating layers 127 may be removed using an etch process so that the first insulating layers 127 may remain along the sidewalls of the word lines WL and on the semiconductor substrate 101 between the word lines WL. Here, the etch process may be performed by using a SiCoNi etching method. As a result, each first insulating layer 127 may have a U-shaped cross section on the semiconductor substrate 101 between the word lines WL. In other words, a groove T may be formed in a central portion of the first insulating layer 127.

Referring to FIG. 10, second insulating layers 129 may be formed on the first insulating layers 127 between the word lines WL so as to form air gaps 131. For example, after the second insulating layers 129 are formed over the entire structure so as to fill the second insulating layers 129 between the word lines WL, a planarization process may be performed until the hard mask layer 123 is exposed, so that the second insulating layers 129 may remain between the word lines WL. The air gaps 131 may be formed in the first and second insulating layers 127 and 129 between the word lines WL by forming the second insulating layers 129 by adjusting processing conditions so as to form protrusions at top corners of the word lines WL.

In addition, interference between the word lines WL may be suppressed by the air gaps 131.

A structure of the semiconductor device manufactured by the above-described method is described below.

The isolation layers 115 including the gaps 117 may be formed in the isolation regions defined between the active regions of the semiconductor substrate 101. The word lines WL, each of which includes a stacked structure of the tunnel insulating layer 103, a floating gate (105 and 113), the dielectric layer 119 and a control gate (121 may be formed on the semiconductor substrate 101 in a direction crossing the isolation layers 115. In addition, the first and second insulating layers 127 and 129 including the air gaps 131 may be formed between the word lines WL. Here, the floating gate may include the silicon layer 105 located between the tunnel insulating layer 103 and the dielectric layer 119, and the grown layers 113 formed on both sidewalls of the silicon layer 105. A width of the floating gate including the silicon layer 105 and the grown layers 113 may be greater than that of the active region. Although the width of the silicon layer 105 corresponds to that of the active region, the grown layers 113 formed along the sidewalls of the silicon layer 105 and located above the isolation regions may allow the width of the floating gate to be greater than the width of the active region.

The isolation layers 115 may be formed at the trenches formed in the isolation regions of the semiconductor substrate 101. The growth inhibiting layers 111 may be formed between the semiconductor substrate 101 and the isolation layers 115, respectively.

The isolation layers 115 may have heights defined from the trenches 109 to the floating gate (105 and 113). The air gap 117 in the isolation layer 115 may extend in parallel to the isolation region. A top portion of each air gap 117 may be located at a height between top and bottom surfaces of the floating gate (105 and 113).

The air gap 131 may be formed in the first and second insulating layers 127 and 129 between the word lines WL. The air gap 131 in the first and second insulating layers 127 and 129 may extend in parallel with the word line WL.

The semiconductor device having the above-described structure manufactured by the above-described method may suppress interference between the word lines and between the active regions. In addition, since the top portion of the air gap 117 formed in the isolation layer 115 may extend between the top and bottom surfaces of the floating gate (105 and 113), interference between the floating gate (105 and 113) and the active region adjacent thereto may also be suppressed.

According to an embodiment of the present invention, operating characteristics and reliability of a semiconductor device may be improved by suppressing the above-mentioned interferences.

What is claimed is:

1. A semiconductor device, comprising:
isolation layers formed in isolation regions defined between active regions of a semiconductor substrate, wherein each of the isolation layers includes a first air gap;
word lines formed over the semiconductor substrate in a direction crossing the isolation layers, wherein each of the word lines includes a stacked structure of a tunnel insulating layer, a floating gate, a dielectric layer and a control gate; and
insulating layers formed between the word lines,
wherein a width of the floating gate is greater than a width of each active region.

2. The semiconductor device of claim wherein the floating gate comprises:
a silicon layer located between the tunnel insulating layer and the dielectric layer; and
grown layers formed on both sidewalls of the silicon layer.

3. The semiconductor device of claim 2, wherein a width of the silicon layer corresponds to a width of each active region.

4. The semiconductor device of claim 2, wherein the grown layers are formed on both sidewalk of the silicon layer and located above the isolation regions.

5. The semiconductor device of claim 1, herein trenches are formed in the isolation regions of the semiconductor substrate, and the isolation layers are formed at the trenches.

6. The semiconductor device of claim 5, further comprising growth inhibiting layers formed between the semiconductor substrate and the isolation layers.

7. The semiconductor device of claim 1, wherein each isolation layer has a height defined from a trench to the floating gate.

8. The semiconductor device of claim wherein the first air gap in each isolation layer extends in parallel with each isolation region.

9. The semiconductor device of claim 1, wherein a top portion of the first air gap is disposed within a height range of said each floating gate and between the floating gates.

10. The semiconductor device of claim 1, further comprising second air gaps formed in the insulating layers between the word lines.

11. The semiconductor device of claim 10, wherein the second air gaps in the insulating layers extend in parallel with the word lines.

12. A method of manufacturing a semiconductor device, the method comprising:
stacking tunnel insulating layers and silicon layers in active regions of the semiconductor substrate and forming trenches in isolation regions between the active regions;
forming grown layers on sidewalls of the silicon layers;
forming isolation layers for filling the trenches and spaces between the silicon layers and forming first air gaps therein;
forming a dielectric layer and a conductive layer over the semiconductor substrate including the isolation layers; and
forming word lines by patterning the conductive layer, the dielectric layer, the silicon layers and the grown layers.

13. The method of claim 12, further comprising forming growth inhibiting layers on exposed surfaces of the trenches before the forming of the grown layers.

14. The method of claim 13, wherein the grown layers are formed by Selective Epitaxial Growth (SEG).

15. The method of claim 12, wherein the grown layers are formed on the sidewalk of the silicon layers and located above the isolation regions.

16. The method of claim 12, wherein the isolation layers have heights defined from the trenches to the silicon layers.

17. The method of claim 12, wherein the first air gaps in the isolation layers extend in parallel with the isolation regions.

18. The method of claim 12, wherein a top portion of each first air gap is formed at a height between top and bottom surfaces of the floating gate.

19. The method of claim 12, further comprising forming insulating layers including second air gaps between the word lines.

20. The method of claim 19, wherein the forming of the insulating layers comprises:
forming first insulating layers along sidewalls of the word lines and over the semiconductor substrate between the word lines; and
forming second insulating layers over the first insulating layers between the word lines to form the second air gaps.

21. A semiconductor device, comprising:
isolation layers formed in isolation regions defined between active regions of a semiconductor substrate, wherein each of the isolation layers includes an air gap;
floating gates each of which is formed over the semiconductor substrate in a direction crossing the isolation layers; and
grown layers formed on both sidewalls of the floating gate,
wherein a top portion of the air gap is disposed within a height range of said each floating gate and between the floating gates.

22. The method of claim 21, further comprising a tunnel insulating layer over the semiconductor substrate, wherein said each floating gate comprises a silicon layer formed over the tunnel insulating layer.

23. The method of claim 21, wherein the grown layers are formed using Selective Epitaxial Growth.

24. The method of claim 23, wherein the grown layers protrude from the floating gates with such a thickness that the isolation layers form the air gap therein.
